(19) United States
(12) Patent Application Publication
(10) Pub. No.: US 2002/0018575 A1
(43) Pub. Date: Feb. 14, 2002

(54) Panel-form loudspeakers

(76) Inventor: Charles Bream, Cambridgeshire (GB)

Correspondence Address: Alan I. Cantor, FOLEY & LARDNER, Washington Harbour, 3000 K Street, N.W., Suite 500, Washington, DC, 20007-5109, US

(21) Appl. No.: 09/814,164

(22) Filed: Mar. 22, 2001

Related U.S. Application Data
(60) Provisional application No. 60/191,485, filed on Mar. 23, 2000.

(30) Foreign Application Priority Data
Mar. 23, 2000 (GB) 0007025.0

(51) Int. Cl. H04R 31/00; H05K 3/30; H04R 1/02; H04R 9/08

(52) U.S. Cl. 381/386; 29/594; 29/832; 381/361

(57) ABSTRACT

A method of making an acoustical member capable of supporting bending wave vibration. The method comprises the steps of providing a panel (12) to form an acoustic radiator; identifying a position (13) on the panel (12) for mounting a vibration transducer (20) to excite bending waves in the panel; and securing a stiffening member (16) to the panel at the position (13) for mounting the transducer to stiffen the panel locally. Also disclosed is a loudspeaker (10) comprising a bending wave panel-form acoustic radiator (12) and a vibration transducer (20) mounted to the panel (12) to excite bending-wave vibration in the panel, with a stiffening member (16) secured to the panel locally of the transducer.

This application claims the benefit of provisional application No. 60/191,485, filed Mar. 23, 2000.

### TECHNICAL FIELD

The invention relates to loudspeakers and, more particularly, to bending wave panel-form loudspeakers, e.g. of the general kind described in International patent application WO97/09842.

### BACKGROUND ART

The technology described in International application WO97/09842 has come to be known as distributed mode or DM technology. Such loudspeakers comprise a stiff lightweight resonant panel and a vibration transducer or exciter mounted to the panel to excite bending-wave vibration in the panel.

It is known that the high frequency performance of bending wave panel-form loudspeakers comprising a lossy or damped panel, may be limited in extension and even localised to the transducer position.

In International patent application WO00/15000, the bending stiffness and/or areal mass density in the panel varies over the area of the panel. In one embodiment, the transducer comprises a coil and the panel is stiffer at the transducer location since the aperture resonance caused by coupling of the coil mass within a finite area is at an advantageously higher frequency for a stiffer panel. In WO00/15000 the panel is designed to have a non-uniform bending stiffness profile. Such a panel is complex to design and produce.

It is an object of the invention to provide a simplified process for improving the acoustic performance of a panel-loudspeaker, in particular the high frequency performance of a lossy or damped panel.

### SUMMARY OF THE INVENTION

According to the invention, a method of making an acoustical member capable of supporting bending wave vibration comprises the steps of providing a panel to form an acoustic radiator, identifying a position on the panel for mounting a vibration transducer to excite bending waves in the panel, and securing a stiffening member to the panel at the position for mounting the transducer to stiffen the panel locally.

The method may comprise the steps of forming, e.g. by cutting or otherwise, a cavity, e.g. a hole or slit, in the panel at the position for mounting the transducer and inserting the stiffening member in the cavity. The method may comprise the step of inserting adhesive between the stiffening member and the panel, the adhesive acting to form a bond between the panel and the stiffening member.

The method thus provides a straightforward process for stiffening a pre-formed panel, e.g. a standard panel with a uniform bending stiffness over the area of the panel, in the locality of the transducer to improve the high frequency performance. The method may be particularly suitable for panels constructed using core materials that exhibit low shear (<30 MPa) and compressive moduli, such as polyurethane and polystyrene non-structural foams. These foams are commonly used in combination with paper-based liners/faceskins for displayboard applications (e.g. panels manufactured from Kapa).

The cavity may be formed centrally of the transducer position. The cavity may be in the form of a slot or a hole. The cavity may be equal in depth to the thickness of the panel. Thus, for example, for a composite panel comprising a core layer sandwiched between skin layers, the method may comprise arranging the stiffening member to extend completely through the panel core and skin layers to increase the shear and/or compression moduli of the panel at the transducer position.

The method may comprise forming the stiffening member from one or more discrete components which may be rod-like or curved. The stiffening member may be formed in the shape of a cross, a star or a circle.

The method may comprise locating the stiffening member entirely within a panel area bounded by the transducer position or alternatively may be located entirely outside the transducer position. The stiffening member may be located so that its centre is coincident with the centre of the transducer position.

The method may comprise arranging the orientation of the stiffening member to be preferential in relation to the principal axes of the panel. The size of the stiffening member may alternatively be adjusted to suit the desired acoustic performance of the loudspeaker.

The stiffening member may be made of carbon, plastics, metals or other materials with a higher bending stiffness than the panel material. The stiffening member may be fibrous and the orientation of the fibre may be preferentially determined.

According to a second aspect of the invention there is provided a loudspeaker comprising a bending wave panel-form acoustic radiator, a vibration transducer mounted to the panel to excite bending-wave vibration in the panel, and a stiffening member which is secured to the panel locally of the transducer. The stiffening member is preferably designed to increase the shear and compression moduli of the panel at the transducer position.

The panel may be a resonant panel, e.g. as described in WO97/09842 and counterpart U.S. application No. 08/707,012, filed Sep. 3, 1996 (the latter application being incorporated herein by reference), and the transducer is adapted to excite resonant bending waves in the panel. The stiffening member may be mounted in a cavity in the panel. The stiffening member may extend completely through the panel to increase the shear and/or compression moduli of the panel at the transducer position. For a composite panel comprising a core layer sandwiched between skin layers, the stiffening member may extend through both core and skin layers or alternatively through only the core layer.

The stiffening member may be mounted centrally of the transducer position. The centre of the stiffening member may be coincident with the centre of the transducer position.

The stiffening member may be cruciform, or star-shaped or circular and may be formed from one or more discrete components which may be rod-like or curved. The stiffening member may be made of carbon, plastics, metals or other material with a higher bending stiffness than the panel material. Alternatively, the stiffening member may be of fibre reinforced plastics with the orientation of the fibre preferentially determined.

### BRIEF DESCRIPTION OF THE DRAWING

Examples that embody the best mode for carrying out the invention are described in detail below and are diagrammatically illustrated in the accompanying drawing, in which:

FIG. 1 is a schematic elevational view of a loudspeaker embodying the present invention;

FIG. 1a is an enlarged cross-section of a stiffener incorporated in the loudspeaker of FIG. 1;

FIG. 2 is a schematic cross sectional view of a portion of the loudspeaker of FIG. 1;

FIG. 3 is a graph of the frequency response for two loudspeakers, one of which embodies the present invention; and

FIGS. 4a to 4l are schematic illustrations of various stiffener shapes.

### DETAILED DESCRIPTION

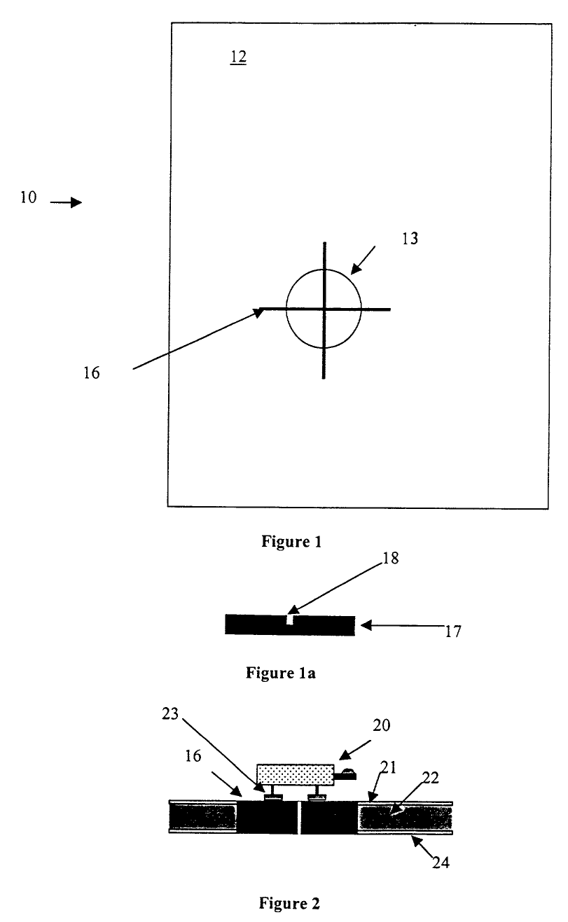

FIG. 1 shows a loudspeaker (10) comprising a resonant panel (12). A vibration transducer (not shown) is mounted to the panel at position (13). The panel is a 5 mm thick rectangular Kapa-Mount™ panel (comprised of 0.33 mm thick aluminium reinforced boxboard liners bonded to a nonstructural rigid polyurethane foam) with dimensions 250 mm by 185 mm. This is typical of a lossy panel constructed using a core with a low shear modulus.

A stiffening member in the form of a cross-shaped stiffener (16) has been inserted into the panel (12) at the transducer position (13). The stiffener (16) is located centrally within the transducer position (13). The stiffener (16) is made of 0.13 mm thick undirectional carbon fibre reinforced polyamide(known in the trade as a CF/PA12) thermoplastic prepreg tape stiffener. The stiffener is constructed from two identical parts (17). FIG. 1a shows each part of the stiffener to be generally rectangular with a small notch (18) at the crossover point.

FIG. 2 shows the location of the stiffener (16) in relation to the transducer (20) and the panel (12). The stiffener (16) is mounted in a slit in the panel (12) and is comparable in thickness to the total thickness of the panel, namely the thickness including both the skins (24) and core (22). The transducer (20) is mounted on a surface (21) of the panel via mounts (23).

The stiffener (16) is inserted using a three-step process:

Slitting of panel including both the skins (24) and core (22) with scalpel (ultrasonic knife or alternative technique may be used in production)

Insertion of epoxy adhesive into slit

Insertion of stiffener

In this way, a stiffener may be inserted in a finished panel.

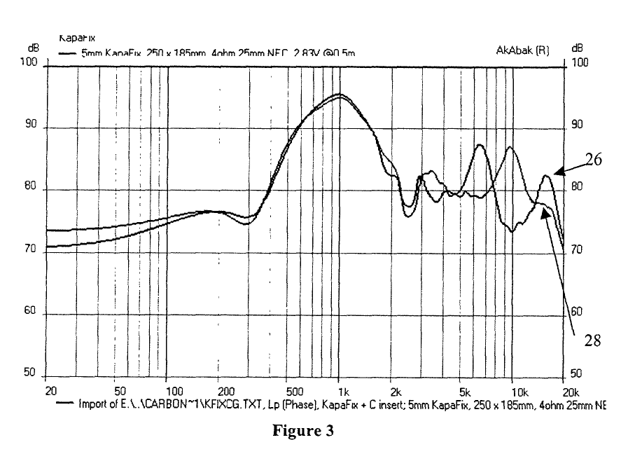

The effect of the stiffener on the frequency performance can clearly be seen in FIG. 3 which shows the frequency response (26) for the panel (12) described above without a stiffener and the frequency response (28) for the same panel with stiffener (16) inserted. The frequency responses were measured on-axis at a distance of 50 cm with a 25 mm 4 ohm NEC transducer with 2.83V.

FIG. 3 shows that the carbon fibre reinforced polyamide stiffener (16) increases the aperture resonance by 3.2 kHz up to 10 kHz with no loss in sensitivity.

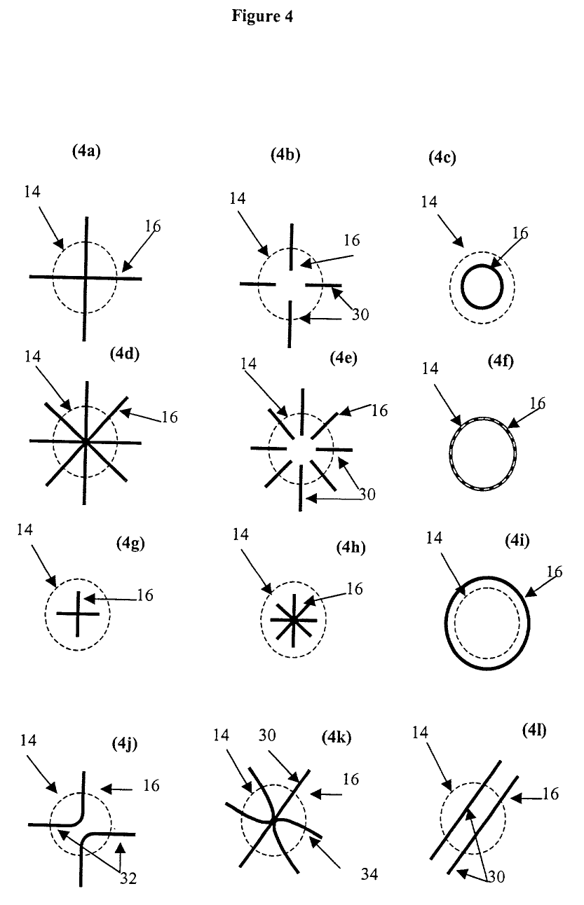

FIGS. 4a to 4l show various embodiments of stiffeners (16) which may be used according to the invention to stiffen a pre-formed panel to improve high frequency performance. The stiffeners (16) have a variety of shapes, for example generally cruciform in FIGS. 4a, 4b and 4g, generally star-shaped in FIGS. 4d, 4e and 4h or circular in FIGS. 4c, 4f and 4i.

The stiffeners (16) are formed from one piece as in FIG. 4c, 4f and 4i or alternatively the stiffeners (16) are formed from several discrete components. The components may be contiguous (e.g., FIGS. 4a, 4d, 4g, 4h, 4k) or spaced apart (e.g., FIGS. 4b, 4e, 4j, 4l). The stiffeners of FIGS. 4b and 4e are formed from 4 and 8 rod-like pieces (30) respectively. The stiffener (16) in FIG. 4j is formed from two generally hyperbolic pieces (32) which are spaced apart. In FIG. 4k the stiffener is formed from two parabolic pieces (34) joined at the bases of the parabolas to a rod-like piece (30). The stiffener in 4l is formed from two parallel rod-like pieces (30). Other arrangements of stiffener components that accomplish substantially the same result will be apparent to those skilled in the art.

The position of the stiffener relative to the transducer position (13) is also indicated in FIGS. 4a to 4l. The transducer mount, which attaches the transducer to the panel (12), has a perimeter (14) indicated by the dashed line in each of these figures. In FIGS. 4c, 4g and 4h the stiffener (16) is located entirely within the perimeter (14) of the transducer mount (i.e., the stiffener lies wholly within the transducer footprint). In contrast, in FIG. 4i the stiffener (16) is located outside the perimeter (14) of the transducer mount (i.e., the stiffener lies wholly outside the transducer footprint), and is concentric therewith. In FIG. 4f, the shape of the stiffener (16) matches the perimeter (14) of the transducer mount (i.e., the stiffener is coextensive with the transducer footprint). In the remaining FIGS. 4a, 4b, 4d, 4e, 4j, 4k and 41, the stiffener (16) crosses the perimeter (14) of the transducer mount. Furthermore, the centre of the stiffener (16) in FIGS. 4a to 4i and 4k coincides with the centre of the transducer perimeter (14).

The invention thus provides a simplified process for improving the acoustic performance of a panel-loudspeaker by adding a stiffener at the transducer position.

The advantages of adding a stiffener are as follows:

Structural integrity of the panel is maintained

Insertion of stiffener is straightforward

The stiffener can be inserted into a finished panel

The high frequency range of a low specification panel (e.g. Kapa™) can be extended with no loss in sensitivity.

It will be appreciated that this local stiffening approach could also apply to higher performance panels such as those containing structural core materials (e.g. polymethacrylimide foam).

1. A method of making an acoustical member capable of supporting bending wave vibration comprising the steps of:
providing a panel to form an acoustic radiator;
identifying a position on the panel for mounting a vibration transducer to excite bending waves in the panel; and
securing a stiffening member to the panel at the position for mounting the transducer to stiffen the panel locally.

2. A method according to claim 1, wherein the step of securing the stiffening member to the panel comprises forming a cavity in the panel at the position for mounting the transducer and inserting the stiffening member in the cavity.

3. A method according to claim 2, wherein the step of securing the stiffening member to the panel further comprises inserting adhesive between the stiffening member and the panel, the adhesive acting to form a bond between the panel and the stiffening member.

4. A method according to claim 3, wherein the cavity is formed centrally of the transducer position.

5. A method according to claim 2, wherein the cavity is formed centrally of the transducer position.

6. A method according to claim 1, wherein the panel is a composite comprising a core layer sandwiched between skin layers, and the step of securing the stiffening member to the panel comprises arranging the stiffening member to extend completely through the panel to increase the shear and/or compression moduli of the panel at the transducer position.

7. A method according to claim 6, wherein the step of securing the stiffening member to the panel comprises forming a cavity in the panel at the position for mounting the transducer and inserting the stiffening member in the cavity.

8. A method according to claim 7, wherein the step of securing the stiffening member to the panel further comprises inserting adhesive between the stiffening member and the panel, the adhesive acting to form a bond between the panel and the stiffening member.

9. A method according to claim 8, wherein the cavity is formed centrally of the transducer position.

10. A method according to claim 1, wherein the step of securing the stiffening member to the panel further comprises inserting adhesive between the stiffening member and the panel, the adhesive acting to form a bond between the panel and the stiffening member.

11. A method of making an acoustical member capable of supporting bending wave vibration comprising the steps of:
providing a panel to form an acoustic radiator, the panel comprising a core layer sandwiched between skin layers;
identifying a position on the panel for mounting a vibration transducer to excite bending waves in the panel;
forming a cavity in the panel centrally of the position for mounting the transducer, the cavity extending completely through the panel;
bonding a substantially cylindrical stiffening member to the panel in the cavity with adhesive, the stiffening member extending completely through the panel, to increase the shear and/or compression moduli of the panel at the transducer position.

12. A method according to claim 11, wherein the stiffening member has a substantially circular cross-section.

13. A method according to claim 12, wherein the stiffening member is coextensive with the transducer footprint.

14. A method according to claim 12, wherein the stiffening member lies wholly within the transducer footprint.

15. A method according to claim 12, wherein the stiffening member lies wholly outside of the transducer footprint.

16. A method of making an acoustical member capable of supporting bending wave vibration comprising the steps of:
providing a panel to form an acoustic radiator;
identifying a position on the panel for mounting a vibration transducer to excite bending waves in the panel; and
securing a stiffening member to the panel at the position for mounting the transducer to stiffen the panel locally, the stiffening member being formed from a plurality of discrete components.

17. A method according to claim 16, wherein the components are contiguous.

18. A method according to claim 17, wherein the step of securing the stiffening member to the panel comprises forming a cavity in the panel at the position for mounting the transducer and inserting the stiffening member components in the cavity with adhesive between the stiffening member components and the panel, the adhesive acting to form a bond between the panel and the stiffening member components.

19. A method according to claim 18, wherein the cavity is formed centrally of the transducer position.

20. A method according to claim 19, wherein the panel is a composite comprising a core layer sandwiched between skin layers, and the step of securing the stiffening member to the panel comprises arranging the stiffening member components to extend completely through the panel to increase the shear and/or compression moduli of the panel at the transducer position.

21. A method according to claim 17, wherein the panel is a composite comprising a core layer sandwiched between skin layers, and the step of securing the stiffening member to the panel comprises arranging the stiffening member components to extend completely through the panel to increase the shear and/or compression moduli of the panel at the transducer position.

22. A method according to claim 16, wherein the components are spaced apart.

23. A method according to claim 22, wherein the step of securing the stiffening member to the panel comprises forming a plurality of cavities in the panel at the position for mounting the transducer and inserting the stiffening member components in the cavities with adhesive between the stiffening member components and the panel, the adhesive acting to form a bond between the panel and the stiffening member components.

24. A method according to claim 23, wherein the cavities are formed in an array arranged centrally of the transducer position.

25. A method according to claim 24, wherein the panel is a composite comprising a core layer sandwiched between skin layers, and the step of securing the stiffening member to the panel comprises arranging the stiffening member components to extend completely through the panel to increase the shear and/or compression moduli of the panel at the transducer position.

26. A method according to claim 22, wherein the panel is a composite comprising a core layer sandwiched between skin layers, and the step of securing the stiffening member to the panel comprises arranging the stiffening member components to extend completely through the panel to increase the shear and/or compression moduli of the panel at the transducer position.

27. A method according to claim 22, wherein the components lie within and extend beyond the transducer footprint.

28. A method according to claim 17, wherein the components lie within and extend beyond the transducer footprint.

29. A method according to claim 17, wherein the components lie wholly within the transducer footprint.

30. A method according to claim 16, wherein the components are preferentially arranged in relation to the principal axes of the panel.

31. A loudspeaker comprising:
a bending wave panel-form acoustic radiator;
a vibration transducer mounted to the panel to excite bending wave vibration in the panel; and
a stiffening member secured to the panel locally of the transducer.

32. A loudspeaker according to claim 31, wherein the stiffening member is mounted in a cavity in the panel.

33. A loudspeaker according to claim 32, wherein the stiffening member is mounted centrally of the transducer position.

34. A loudspeaker according to claim 32, wherein the panel is a composite comprising a core layer sandwiched between skin layers, and wherein the stiffening member extends completely through the panel to increase the shear and/or compression moduli of the panel at the transducer position.

35. A loudspeaker according to claim 34, wherein the stiffening member is mounted centrally of the transducer position.

36. A loudspeaker according to claim 34, wherein the stiffening member is made of a material with a higher bending stiffness than the panel material.

37. A loudspeaker according to claim 36, wherein the stiffening member is made of a material selected from the group consisting of carbon, metal, plastics and fibre reinforced plastics.

38. A loudspeaker according to claim 31, wherein the shape of the stiffening member is selected from the group consisting of cruciform shapes, star shapes and circular shapes.

39. A loudspeaker according to claim 38, wherein the stiffening member is coextensive with the transducer footprint.

40. A loudspeaker according to claim 38, wherein the stiffening member lies wholly within the transducer footprint.

41. A loudspeaker according to claim 38, wherein the stiffening member lies wholly outside of the transducer footprint.

42. A loudspeaker according to claim 31, wherein the stiffening member comprises two spaced, divergent, generally hyperbolic components.

43. A loudspeaker according to claim 42, wherein the hyperbolic components lie within and extend beyond the transducer footprint.

44. A loudspeaker according to claim 31, wherein the stiffening member comprises two contiguous, divergent, generally parabolic components and a straight component that bisects the parabolic components.

45. A loudspeaker according to claim 44, wherein the parabolic and straight components lie within and extend beyond the transducer footprint.

46. A loudspeaker according to claim 31, wherein the stiffening member comprises two spaced, parallel, straight components.

47. A loudspeaker according to claim 46, wherein the straight components lie within and extend beyond the transducer footprint.

48. A loudspeaker according to claim 31, wherein the panel is a resonant panel and the transducer is adapted to excite resonant bending waves in the panel.

49. A loudspeaker comprising:
a bending wave panel-form acoustic radiator comprising a core layer sandwiched between skin layers;
a vibration transducer mounted to the panel to excite bending wave vibration in the panel; and
a stiffening member secured to the panel locally of the transducer, the stiffening member extending completely through the panel and bonded thereto to increase the shear and/or compression moduli of the panel at the transducer position.

50. A loudspeaker according to claim 49, wherein the shape of the stiffening member is selected from the group consisting of cruciform shapes, star shapes and circular shapes.

51. A loudspeaker according to claim 50, wherein the stiffening member is coextensive with the transducer footprint.

52. A loudspeaker according to claim 50, wherein the stiffening member lies wholly within the transducer footprint.

53. A loudspeaker according to claim 50, wherein the stiffening member lies wholly outside of the transducer footprint.

54. A loudspeaker according to claim 49, wherein the stiffening member comprises two spaced, divergent, generally hyperbolic components.

55. A loudspeaker according to claim 54, wherein the hyperbolic components lie within and extend beyond the transducer footprint.

56. A loudspeaker according to claim 49, wherein the stiffening member comprises two contiguous, divergent, generally parabolic components and a straight component that bisects the parabolic components.

57. A loudspeaker according to claim 56, wherein the parabolic and straight components lie within and extend beyond the transducer footprint.

58. A loudspeaker according to claim 49, wherein the stiffening member comprises two spaced, parallel, straight components.

59. A loudspeaker according to claim 58, wherein the straight components lie within and extend beyond the transducer footprint.

60. A loudspeaker according to claim 49, wherein the panel is a resonant panel and the transducer is adapted to excite resonant bending waves in the panel.

61. A loudspeaker comprising:
a bending wave panel-form acoustic radiator;
a vibration transducer mounted to the panel to excite bending wave vibration in the panel; and
a stiffening member secured to the panel locally of the transducer, the stiffening member being formed from a plurality of discrete components.

62. A loudspeaker according to claim 60, wherein the shape of the stiffening member is selected from the group consisting of cruciform shapes and star shapes.

63. A loudspeaker according to claim 62, wherein the stiffening member lies wholly within the transducer footprint.

64. A loudspeaker according to claim 63, wherein the components are contiguous.

65. A loudspeaker according to claim 62, wherein the components lie within and extend beyond the transducer footprint.

66. A loudspeaker according to claim 65, wherein the components are contiguous.

67. A loudspeaker according to claim 65, wherein the components are spaced apart.

68. A loudspeaker according to claim 61, wherein the stiffening member comprises two spaced, divergent, generally hyperbolic components.

69. A loudspeaker according to claim 68, wherein the hyperbolic components lie within and extend beyond the transducer footprint.

70. A loudspeaker according to claim 61, wherein the stiffening member comprises two contiguous, divergent, generally parabolic components and a straight component that bisects the parabolic components.

71. A loudspeaker according to claim 70, wherein the parabolic and straight components lie within and extend beyond the transducer footprint.

72. A loudspeaker according to claim 61, wherein the stiffening member comprises two spaced, parallel, straight components.

73. A loudspeaker according to claim 72, wherein the straight components lie within and extend beyond the transducer footprint.

74. A loudspeaker according to claim 61, wherein the panel is a resonant panel and the transducer is adapted to excite resonant bending waves in the panel.
